(19) United States
(12) Patent Application Publication
(10) Pub. No.: US 2009/0321883 A1
(43) Pub. Date: Dec. 31, 2009

(54) SILICON SUBSTRATE FOR SOLID-STATE IMAGING DEVICE AND METHOD FOR MANUFACTURING THE SAME

(75) Inventor: Kazunari KURITA, Tokyo (JP)

Correspondence Address: GREENBLUM & BERNSTEIN, P.L.C., 1950 ROLAND CLARKE PLACE, RESTON, VA, 20191, US

(73) Assignee: SUMCO CORPORATION, Tokyo (JP)

(21) Appl. No.: 12/491,404

(22) Filed: Jun. 25, 2009

(30) Foreign Application Priority Data
Jun. 30, 2008 (JP) 2008-171259

(51) Int. Cl. H01L 29/32; H01L 21/322

(52) U.S. Cl. 257/617; 438/476; 257/E21.321; 257/E29.107

(57) ABSTRACT

This method for manufacturing a silicon substrate for a solid-state imaging device, includes: a carbon compound layer forming step of forming a carbon compound layer on the surface of a silicon substrate; an epitaxial step of forming a silicon epitaxial layer on the carbon compound layer; and a heat treatment step of subjecting the silicon substrate having the epitaxial layer formed thereon to a heat treatment at a temperature of 600 and 800° C. for 0.25 to 3 hours so as to form gettering sinks that are complexes of carbon and oxygen below the epitaxial layer. This silicon substrate for a solid-state imaging device is manufactured by the above-mentioned method and includes: n epitaxial layer positioned on the surface of a silicon substrate; and a gettering layer which is positioned below the epitaxial layer and includes BMDs having a size of 10 to 100 nm at a concentration of 1.0×10⁶ to 1.0×10⁹ atoms/cm³.

### BACKGROUND OF THE INVENTION

1. Field of the Invention

The present invention relates to a silicon substrate for a solid-state imaging device and a method for manufacturing the same, and in particular, the present invention relates to a technique suitable for improving the gettering effect of a silicon substrate used for manufacturing a solid-state imaging device so as to suppress white spots.

This application claims priority on Japanese Patent Application No. 2008-171259, filed on Jun. 30, 2008, the content of which is incorporated herein by reference.

2. Description of Related Art

A solid-state imaging device is manufactured by forming a circuit on a single-crystal silicon substrate. When heavy metal is incorporated as impurities into the silicon substrate, the electrical characteristics of the solid-state imaging device markedly deteriorate.

Heavy metal is incorporated as impurities into the silicon substrate by the following causes: metal contamination during the manufacturing process of a silicon substrate; and heavy metal contamination during the manufacturing process of a solid-state imaging device. With regard to the former, it is thought that when an epitaxial layer is grown on a single-crystal silicon substrate, a contamination occurs by heavy metal particles that are generated from epitaxial furnace members, and a contamination occurs by heavy metal particles that are generated due to the corrosion of metals of pipe materials since chlorine gas is used. Metal contamination during an epitaxial step has been lessened by continued effort, such as, replacing the epitaxial furnace members with corrosive-resistance materials. However, it is not easy to completely avoid metal contamination in the epitaxial step.

Therefore, in the related art, in order to avoid the metal contamination in the epitaxial step, the following method has been applied: forming a gettering layer inside a silicon substrate; or using a substrate which has a high gettering effect to getter heavy metal, such as a high-concentration boron substrate.

With regard to the latter, there is concern that heavy metal contamination of a silicon substrate occurs in an ion implantation step, a diffusion step, and an oxidation heat treatment step of a device manufacturing process. In the related art, in order to avoid heavy metal contamination at or in the vicinity of a device active layer, the following methods have been used: an intrinsic gettering method of forming oxygen precipitates in a silicon substrate; and an extrinsic gettering method of forming gettering sites, such as backside damages, in the rear surface of a silicon substrate.

However, with regard to the gettering method in the related art, in the case of the intrinsic gettering method, since it is necessary to form oxygen precipitates in the silicon substrate in advance, the intrinsic gettering method requires multi-stage heat treatment processes; therefore, there is concern that it causes an increase in manufacturing costs. In addition, since it is necessary to conduct a heat treatment at a high temperature for a long time, there is concern that the metal contamination of the silicon substrate occurs. On the other hand, in the case of the extrinsic gettering method, since the backside damages or the like are formed in the rear surface of the silicon substrate, particles are generated from the rear surface during the device manufacturing process, which result in device defects.

Patent Document 1 discloses a technique of implanting carbon ions at a predetermined dose into a surface of a silicon substrate to form a silicon epitaxial layer in the surface, in order to reduce white spots which are generated due to a dark current and affect the electrical characteristics of a solid-state imaging device.

Patent Document 2 discloses that in the case where a substrate in which carbon ions are implanted is used as a substrate for a solid-state imaging device, it becomes highly dependent on the maximum achieving temperature of a CCD manufacturing process.

In Patent Document 3, an example of the EG method is disclosed (paragraph [0005]), and a technique related to the implantation of carbon ions is also disclosed.

However, an intrinsic gettering method in which an oxygen precipitation heat treatment is conducted to form oxygen precipitates before the epitaxial growth, or an ion implantation method in which ions such as carbon ions are implanted into a silicon substrate has been used as a method for manufacturing a silicon substrate for a solid-state imaging device. However, there is concern that heavy metal contamination occurs during both of the silicon substrate manufacturing processes. Therefore, it is necessary to suppress metal contamination during the silicon substrate manufacturing processes.

In addition, in Patent Document 2, there is concern that in the case in which a carbon-implanted substrate is subjected to a heat treatment at high temperatures, crystal defects (for example, crystal lattice strain) formed by the implantation of carbon ions are relaxed; thereby, the function of gettering sinks is likely to deteriorate. Accordingly, the formation of gettering sinks needs to be naturally progressed during the CCD manufacturing process (device manufacturing process).

Since there is a limit on the gettering effect of the gettering sinks formed by the implantation of carbon ions, for example, a scheme has been made to put an upper limit on the device processing temperature after forming the epitaxial layer as described above. However, this scheme constitutes a limiting factor during the device manufacturing process.

In addition, since the gettering effect of the gettering sinks formed by the implantation of carbon ions tends to decrease after the forming of the epitaxial layer, it is difficult to avoid the generation of particles during the above-mentioned device manufacturing process. Therefore, it is also an important task to provide a sufficient gettering effect in the device manufacturing process.

In addition, as for the method for manufacturing a silicon substrate for a solid-state imaging device, in the intrinsic gettering method in which the oxygen precipitation heat treatment is conducted to form oxygen precipitates before the epitaxial growth, or in the ion implantation method in which ions such as carbon ions are implanted into a silicon substrate, there is concern that heavy metal contamination occurs during the silicon substrate manufacturing processes. Therefore, it is necessary to suppress metal contamination during the silicon substrate manufacturing processes.

Patent Document 1: Japanese Unexamined Patent Application, First Publication No. H06-338507

Patent Document 2: Japanese Unexamined Patent Application, First Publication No. 2002-353434

Patent Document 3: Japanese Unexamined Patent Application, First Publication No. 2006-313922

### SUMMARY OF THE INVENTION

The invention has been made in order to solve the above-mentioned problems, and objects of the invention are as follows:

1. To provide a silicon substrate for a solid-state imaging device capable of suppressing heavy metal contamination in a process of manufacturing a solid-state imaging device (device manufacturing process); thereby, solving problems such as the generation of heavy metal particles.

2. To provide a silicon substrate for a solid-state imaging device capable of manufacturing a high-performance solid-state imaging device with excellent electrical characteristics, and the solid-state imaging device is obtained by forming a circuit on the above-mentioned silicon substrate.

3. To suppress metal contamination in a process of manufacturing a silicon substrate for a solid-state imaging device.

4. To attain a reduction in manufacturing cost needed for a method for manufacturing a silicon substrate for a solid-state imaging device, as compared with the conventional gettering methods, in particularly, a gettering method using an implantation of carbon ions.

5. To provide the above-described silicon substrate for a solid-state imaging device together with the advantageous manufacturing method.

The inventors examined techniques capable of avoiding heavy metal contamination on a silicon substrate without an increase in manufacturing cost in the manufacturing process of a solid-state imaging device. First, a gettering method using the implantation of carbon ions was examined. The gettering effect obtained by the implantation of carbon ions generally arises from oxides, and the oxides are precipitated while distortions (strains) of a silicon lattice caused by ion implantation with high energy act as origins of the precipitates. These strains of the lattice are concentrated on an ion-implanted narrow region, and the strains around the oxides are easily relaxed, for example, during a heat treatment at high temperatures in the device manufacturing process. Considering these, the inventors have found that the gettering effect is insufficient particularly in the heat treatment of the device manufacturing process.

The inventors examined in detail the operation of carbon contributing to the formation of gettering sinks in the silicon substrate. The inventors have found the followings. By solid-solubilizing carbon in the silicon lattice in a manner that substitutes silicon with carbon without forcibly introducing carbon by the ion-implantation, carbon/oxygen-based precipitates (complexes of carbon and oxygen) involving dislocations are generated at high density (high-density defects occur due to the complexes of carbon and oxygen) while the carbon at substitution site acts as an origin of the generation during, for example, the device manufacturing process. These carbon/oxygen-based precipitates provide a high gettering effect. In addition, it was also found that such substituted carbon can only be introduced by including carbon into a silicon single crystal in a solid-solubilized state.

In addition, it was also discovered that suitable agglutination of oxygen precipitates is likely to occur in a silicon single crystal doped with B (boron) during a heat treatment as compared with other dopants. This is thought to be caused by the fact that an interaction between B (boron) and point defects (holes and interstitial silicon) is accelerated; thereby, the formation of oxygen precipitate nuclei is facilitated.

It was proved that such suitable agglutination of oxygen precipitates during the heat treatment which is caused by boron significantly occurs in a silicon crystal having a high oxygen concentration.

According to the above-mentioned findings, the inventors have completed the invention.

The method for manufacturing a silicon substrate for a solid-state imaging device of the present invention includes: a carbon compound layer forming step of forming a carbon compound layer on the surface of a silicon substrate; an epitaxial step of forming a silicon epitaxial layer on the carbon compound layer; and a heat treatment step of subjecting the silicon substrate having the epitaxial layer formed thereon to a heat treatment at a temperature of 600 and 800° C. for 0.25 to 3 hours so as to form gettering sinks that are complexes of carbon and oxygen below the epitaxial layer.

With regard to the method for manufacturing a silicon substrate for a solid-state imaging device of the present invention, in the carbon compound layer forming step, the carbon compound layer may be formed to have a growth thickness of 0.1 to 1.0 μm.

In the carbon compound layer forming step, the carbon compound layer may be formed which has a carbon concentration of 1×10¹⁶ to 1×10²⁰ atoms/cm³, and an oxygen concentration of 1.0×10¹⁸ to 1.0×10¹⁹ atoms/cm³.

In the carbon compound layer forming step, the carbon compound layer may be formed by using an organometallic compound gas and a gas containing oxygen as gas sources.

The epitaxial step may include: forming a first silicon epitaxial layer on the carbon compound layer; lowering the ambient temperature to 1000° C. or less after forming the first silicon epitaxial layer; and forming a second silicon epitaxial layer on the first silicon epitaxial layer.

In the carbon compound layer forming step, carbon compounds may be adsorbed onto the surface of the silicon substrate using an organometallic compound gas and a gas containing oxygen as gas sources, and then the silicon substrate may be subjected to a rapid thermal processing so as to diffuse the carbon compounds into the silicon substrate, thereby, the carbon compound layer is formed.

The method for manufacturing a silicon substrate for a solid-state imaging device of the present invention may further include forming a buffer layer directly on the carbon compound layer.

The method for manufacturing a silicon substrate for a solid-state imaging device of the present invention may further comprises forming an oxide film on the epitaxial layer.

A single crystal silicon substrate doped with boron at a concentration of 1×10¹⁵ to 1×10¹⁹ atom/cm³ may be used as the silicon substrate.

The silicon substrate for a solid-state imaging device of the present invention is manufactured by the method for manufacturing a silicon substrate for a solid-state imaging device of the present invention and includes: an epitaxial layer positioned on the surface of a silicon substrate; and a gettering layer which is positioned below the epitaxial layer and includes BMDs having a size of 10 to 100 nm at a concentration of 1.0×10⁶ to 1.0×10⁹ atoms/cm³.

In accordance with the present invention, a carbon compound layer is formed on a silicon substrate consisting of a CZ crystal, and a silicon epitaxial layer is formed thereon. Then, by utilizing a process (a heat treatment) of manufacturing a solid-state imaging device, oxygen precipitates which are carbon/oxygen-based complexes, that is, gettering sinks are formed below the epitaxial layer. In a device manufacturing process, heavy metal contamination (contamination by heavy metal particles) can be avoided by these gettering sinks. As a result, it is possible to suppress the diffusion of heavy metal to a buried photodiode or the like; thereby, defects do not occur in a transistor and the buried photodiode which constitute a solid-state imaging device. Therefore, the generation of white defects can be prevented in the solid-state imaging device. Accordingly, it is possible to improve qualities such as the electrical characteristics of the solid-state imaging device and to enhance the yield of the solid-state imaging device.

In addition, with regard to the present invention, in an imaging device manufacturing process, even in a low-temperature heat treatment step, minute oxygen precipitates involving secondary dislocations can be formed at high density immediately below the epitaxial layer. Accordingly, it is possible to maintain sufficient gettering effect even in the low-temperature heat treatment step.

In particular, in the case in which the temperature range of the heat treatment step is 600 to 800° C., it is possible to form oxygen precipitates at high density below the epitaxial layer, so that high gettering effect can be expected. Therefore, in the case where a solid-state imaging device is manufactured by using the substrate of the present invention, the electrical characteristics of the solid-state imaging device can be improved. Accordingly, it is possible to enhance the yield of the solid-state imaging device.

In a conventional method for manufacturing a silicon substrate for a solid-state imaging device, since the growth temperature is higher than 1000° C., there is concern that metal contamination occurs from an epitaxial furnace. In contrast, in accordance with the present invention, it is possible to set the growth temperature of the silicon epitaxial layer to be 1000° C. or less. Therefore, as compared with the conventional technique, it is possible to suppress heavy metal contamination from the epitaxial furnace.

In addition, in the conventional method for manufacturing a silicon substrate for a solid-state imaging device, in order to improve gettering effect, the implantation of carbon ions was performed on the epitaxial substrate. An ion implanter required high operational costs, and reductions in manufacturing costs were limited. In contrast, in accordance with the present invention, it is possible to form gettering sinks by using only the gas sources. Therefore, a silicon substrate for a solid-state imaging device can be manufactured at low cost, and it is possible to reduce manufacturing cost.

### BRIEF DESCRIPTION OF THE DRAWINGS

FIG. 1 is a front cross-sectional view showing a method for manufacturing a silicon substrate according to a first embodiment of the present invention.

FIG. 2 is a flowchart showing the manufacturing method according to the first embodiment of the present invention.

FIG. 3 is a view showing a manufacturing process of a solid-state imaging device.

FIG. 4 is a view explaining heat treatments in Examples of the present invention.

FIG. 5 is a front cross-sectional view showing a method for manufacturing a silicon substrate according to the second embodiment of the present invention.

FIG. 6 is a flowchart showing the manufacturing method according to the second embodiment of the present invention.

### DETAILED DESCRIPTION OF THE INVENTION

### First Embodiment

Hereinafter, a first embodiment of the invention will be described with reference to the accompanying drawings.

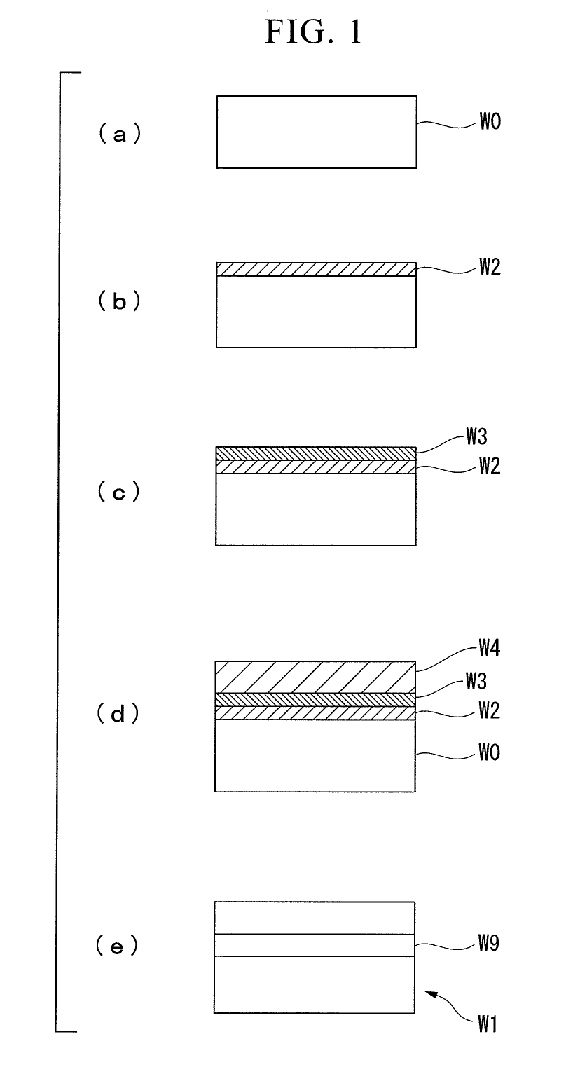

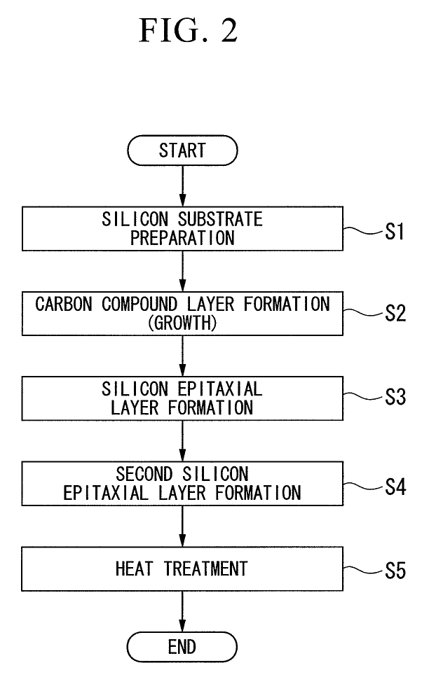

FIG. 1 is a front cross-sectional view showing a method for manufacturing a silicon substrate according to the present embodiment. FIG. 2 is a flowchart showing the manufacturing method according to the present embodiment. In the figure, reference numeral W0 denotes a silicon substrate.

The method for manufacturing a silicon substrate for a solid-state imaging device according to the present embodiment includes, as shown in FIG. 2, a silicon substrate preparing step S1, a carbon compound layer forming step S2, a silicon epitaxial layer forming step S3, a second silicon epitaxial layer forming step S4, and a heat treatment step S5.

According to the present embodiment, in the silicon substrate preparing step S1 shown in FIG. 2, at first, polysilicon that is the raw material of a silicon crystal is placed in, for example, a quartz crucible. Simultaneously, as a dopant, boron (B) is added in the case of manufacturing a P-type substrate, and arsenic or the like is added in the case of manufacturing an N-type substrate. Thereafter, a Czochralski (CZ) crystal is pulled while controlling oxygen at a concentration level Oi by, for example, a CZ method.

Crystals manufactured by the Czochralski method, including a CZ crystal grown by applying a magnetic field, are called CZ crystals.

In the step of processing the silicon substrate (wafer) W0, in accordance with ordinary methods, a CZ crystal is sliced by a cutting apparatus such as an ID saw, a wire saw, or the like to obtain a silicon wafer, and the obtained silicon wafer is subjected to an annealing, and then the surface of the annealed silicon wafer is subjected to surface treatments such as polishing, cleaning, and the like. In addition to these processes, there are various processes such as wrapping, cleaning, grinding, and the like. Modifications of the order of the processes and omissions of the processes can be made according to the purpose of use.

Next, the surface of the above-mentioned mirror-processed silicon substrate W0 is subjected to a gas etching using hydrogen or hydrogen chloride; thereby, contaminants that are adsorbed onto a surface oxide film or the surface are removed to prepare the silicon substrate W0 as shown in FIG. 1(a).

Otherwise, after the mirror processing, a silicon epitaxial layer which is not shown may be formed in advance. In this case, after the surface of the silicon substrate W0 is subjected to the mirror processing, RCA cleaning which is a combination of, for example, SC1 and SC2, is conducted in order to grow an epitaxial layer. Then, the silicon substrate W0 is put into an epitaxial growth furnace, and the epitaxial layer is grown by any one of the various CVD (chemical vapor deposition) methods.

Next, in the carbon compound layer forming step S2 shown in FIG. 2, a carbon compound layer W2 is grown on the surface of the silicon substrate W0 as shown in FIG. 1B. Here, gas sources of organometallic compounds and oxygen are introduced to the surface of the silicon substrate W0 to form the carbon compound layer W2.

In this case, as the gas source of the organometallic compounds, there is an organic silane gas source such as trimethylsilane or the like, and as the gas source of oxygen, there is a gas source containing oxygen such as O₂, CO₂, or N₂O. With regard to forming conditions such as concentrations, film thicknesses, and the like, the ratio of the gas sources (the gas source of organometallic compound: the gas source of oxygen) introduced to the epitaxial growth furnace is preferably in a range of 3:2 to 5:1, more preferably, 4:2, 3:2, 2:1, or 5:1, and most preferably, 5:1. Simultaneously, it is preferable that the temperature conditions or the like be in a range of 600 to 1000° C.

In addition, the supply time and the heating time of the gas sources are controlled to form the carbon compound layer W2 having the growth thickness of 0.1 to 1.0 μm. The thickness of the carbon compound layer W2 is determined by the penetration depth in a visible light region for a silicon crystal. By setting the thickness of the carbon compound layer W2 to be in a range of 0.1 to 1.0 μm, the thickness can be matched up with the penetration depth of visible light.

Further, it is preferable to form the carbon compound layer W2 having a carbon concentration of 1×10¹⁶ to 1×10²⁰ atoms/cm³ and an oxygen concentration of 1.0×10¹⁸ to 1.0×10¹⁹ atoms/cm³. In this case, the formation of complexes of carbon and oxygen as will be described later can be accelerated to its maximum level.

Next, in the silicon epitaxial layer forming step S3 shown in FIG. 2, a first epitaxial layer W3 is formed directly on the surface of the carbon compound layer W2 as shown in FIG. 1(c). Specifically, in a state where the temperature of the substrate having the carbon compound layer W2 formed thereon, is maintained to be 1000° C. or less, the first epitaxial layer W3 is grown directly on the carbon compound layer W2 by using disilane or monosilane gas. In the case in which the substrate temperature is set to be higher than 1000° C., there is a possibility that carbon diffuses outward from the carbon compound layer W2, and there is concern that this may cause a decline in the gettering effect. Therefore, the substrate temperature is set to be 1000° C. or less.

Here, it is preferable that the thickness of the first epitaxial layer W3 be in a range of 2 to 9 μm so as not to allow carbon in the carbon compound layer W2 to affect the device forming region of a solid-state imaging device.

In the second silicon epitaxial layer forming step S4 shown in FIG. 2, a second epitaxial layer W4 is grown on the surface of the first epitaxial layer W3 as shown in FIG. 1(d). Specifically, similarly to the silicon epitaxial layer forming step S3, in a state where the temperature of the substrate is maintained to be 1000° C. or less, the second epitaxial layer W4 is formed on the surface of the first epitaxial layer W3 by using disilane or monosilane gas.

Here, it is preferable that the ambient temperature be lowered to be 1000° C. or less once, between the silicon epitaxial layer forming step S3 and the second silicon epitaxial layer forming step S4. As a result, it is possible to prevent the outward diffusion of the impurities, such as carbon, which are added in the epitaxial layer.

In addition, the second epitaxial layer W4 can be grown under the same conditions, including an atmosphere gas composition, a film formation temperature, and the like, as those of the first epitaxial layer W3.

Here, it is preferable that the thickness of the second epitaxial layer W4 be in a range of 2 to 9 μm for the purpose of improving the spectral sensitivity characteristics of the solid-state imaging device.

In the heat treatment step S5 shown in FIG. 2, by performing a heat treatment in a device manufacturing process of a solid-state imaging device, oxygen precipitates which are complexes of carbon and oxygen (a carbon/oxygen-based precipitate) are precipitated. As shown in FIG. 1(e), by utilizing the oxygen precipitates, a gettering layer W9 which has an ability to form gettering sinks having a high gettering efficiency to getter heavy metal, is formed at the position corresponding to the carbon compound layer W2 and the vicinity thereof; thereby, a silicon substrate W1 is completed. This gettering layer W9 is formed directly below the epitaxial layer.

Since the carbon compound layer W2 is a carbon-rich layer, it can be expected that the oxygen precipitation be accelerated by a low-temperature heat treatment at a temperature of 600 to 800° C. in this heat treatment step S5.

In addition, if necessary, an oxide film may be formed on the surface of the silicon substrate W1 in which the gettering sinks are formed, and a nitride film may also be formed on the oxide film. In a manufacturing process (a device manufacturing process) of a solid-state imaging device as will be described later, a buried photodiode is formed at the position corresponding to the second epitaxial layer W4; thereby, the solid-state imaging device is manufactured.

Considering restrictions in the design of the driving voltage of a transfer transistor, it is preferable that the thickness of the oxide film be in a range of 50 to 100 nm, and the thickness of the nitride film, more specifically, the thickness of a polysilicon gate film of the solid-state imaging device, be in a range of 1.0 to 2.0 μm.

As described above, by performing the heat treatment in the manufacturing process of a solid-state imaging device, oxygen precipitates which are carbon/oxygen-based complexes are precipitated while the carbon at substitution site acts as an origin of the precipitates in the carbon compound layer W2. These oxygen precipitates become gettering sinks and getter heavy metal in the manufacturing process of a solid-state imaging device; thereby, contamination by heavy metal (contamination by heavy metal particles) can be suppressed.

Here, the gettering layer W9 of the silicon substrate W1 provided in the device manufacturing process is a silicon layer containing carbon which arises from the carbon compound layer W2. However, since oxygen precipitate nuclei or the oxygen precipitates are shrunken by a heat treatment for growing the epitaxial layers W3 and W4, marked oxygen precipitates do not exist in the carbon compound layer W2 that is included in the steps prior to the heat treatment step S5.

Accordingly, in order to ensure gettering sinks for gettering heavy metal, after the epitaxial layer W4 is grown, it is necessary to conduct a low-temperature heat treatment as the heat treatment step S5, preferably at a temperature of 600 to 800° C. for 0.25 to 3 hours so as to precipitate oxygen precipitates which are carbon/oxygen-based complexes while the carbon at substitution site acts as an origin of the precipitates. Furthermore, it is preferable that this low-temperature heat treatment for precipitating the oxygen precipitates be conducted before the device manufacturing process.

In the present invention, the oxygen precipitates that are the carbon/oxygen-based complexes (oxygen precipitates that are boron/carbon/oxygen-based complexes in the case of using a silicon substrate doped with boron) refer to precipitates that are complexes (clusters) containing carbon. Through the present specification, oxygen precipitates, oxygen precipitates that are carbon/oxygen-based complexes, carbon/oxygen-based precipitates, complexes of carbon and oxygen, and BMDs are illustrated to be the same.

If the carbon compound layer W2 that is a silicon layer containing carbon is used as a base material, the oxygen precipitates are spontaneously precipitated in the entire carbon compound layer W2 and adjacent portions that are diffusion regions of carbon in an initial stage of the device manufacturing process. As a result, it is possible to form gettering sinks having a high gettering effect for metal contamination at a region (gettering layer W9) immediately below the epitaxial layer in the device manufacturing process. Therefore, it is possible to form a gettering layer capable of exerting gettering effect near the epitaxial layers W3 and W4.

In order to achieve excellent gettering effect, it is preferable that the oxygen precipitates (BMD) that are carbon/oxygen-based complexes have a size of 10 to 100 nm and exist at a concentration of 1.0×10⁶ to 1.0×10⁹ atoms/cm³ in the gettering layer W9.

The reason why the size of the oxygen precipitate is limited to be not less than the lower limit of the above-mentioned range is to increase the probability of gettering interstitial impurities (for example, heavy metal) by using the effect of strains occurring in interfaces between silicon atoms in the matrix and the oxygen precipitates. On the other hand, if the size of the oxygen precipitate is greater than the above-mentioned range, problems appear such as the reduction in the strength of the substrate, the occurrence of dislocations in the epitaxial layers W3 and W4, and the like, which is not preferable.

In addition, it is preferable that the concentration of the oxygen precipitates in the gettering layer W9 be in the above-mentioned range because the gettering of heavy metal in the silicon crystal depends on strains occurring in the interface between the silicon atoms in the matrix and the oxygen precipitates and the interface level density (volume density).

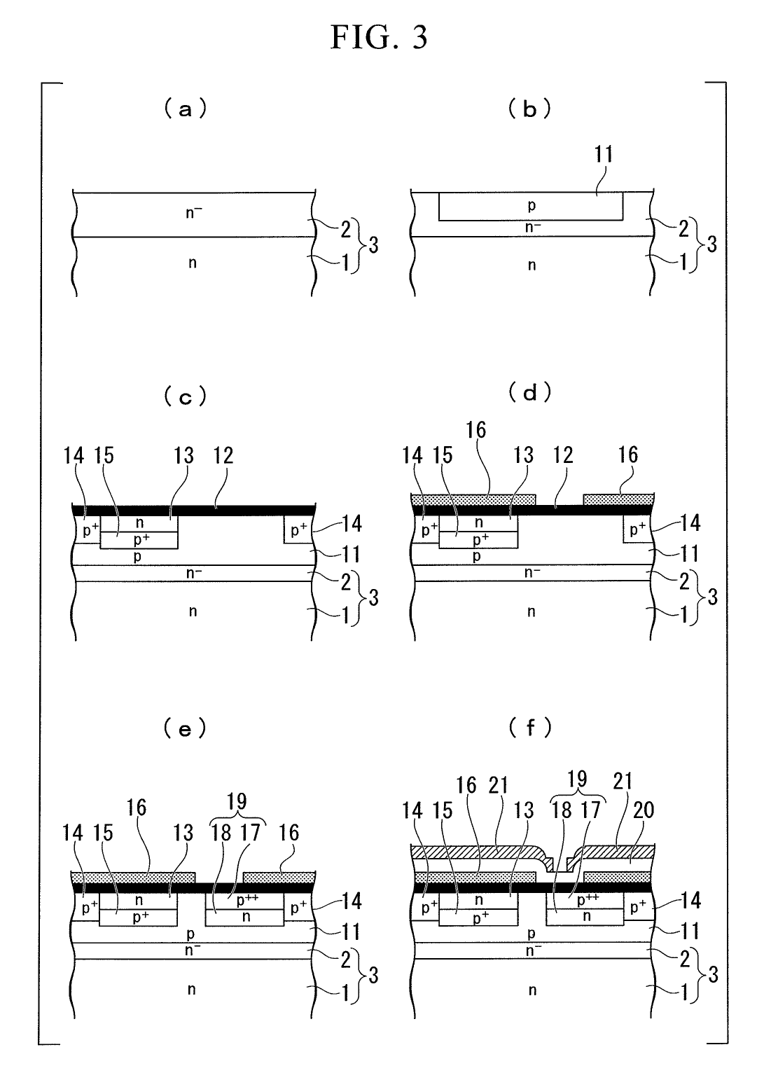

As the manufacturing process of a solid-state imaging device (device manufacturing process) as described above, a general manufacturing process of a solid-state imaging device can be utilized. A CCD manufacturing process is shown in FIG. 3 as an example; however, the device manufacturing process is not limited thereto.

Specifically, in the device manufacturing process, at first, as shown in FIG. 3(a), a semiconductor substrate 3 corresponding to the silicon substrate shown in FIG. 1(d) is prepared. Here, reference numeral 1 corresponds to the whole of the silicon substrate W0, the carbon compound layer W2, and the first epitaxial layer W3, and an epitaxial layer 2 corresponds to the second epitaxial layer W4.

Then, as shown in FIG. 3(b), a first p-type well region 11 is formed at a predetermined position in the epitaxial layer 2. Thereafter, as shown in FIG. 3(c), a gate insulating film 12 is formed on the surface of the semiconductor substrate 3, and n-type and p-type impurities are selectively implanted into the first p-type well region 11 by ion implantation to form an n-type transfer channel region 13, a p-type channel stop region 14, and a second p-type well region 15 which constitute a vertical transfer register.

Then, as shown in FIG. 3(d), a transfer electrode 16 is formed at a predetermined position on the surface of the gate insulating film 12. Thereafter, as shown in FIG. 3(e), n-type and p-type impurities are selectively implanted between the n-type transfer channel region 13 and the second p-type well region 15 to form a photodiode 19 having a laminated structure of a p-type positive charge storage region 17 and an n-type impurity diffusion region 18.

Then, as shown in FIG. 3(f), an interlayer insulating film 20 is formed on the surface of the semiconductor substrate 3, and a light-shielding film 21 is formed on the surface of the interlayer insulating film 20 except for the portion immediately above the photodiode 19; thereby, a solid-state imaging device 10 is manufactured.

In the above-mentioned device manufacturing process, a heat treatment is generally performed at a temperature of 600 to 1000° C. during, for example, a gate oxide film forming step, a device separation step, and a polysilicon gate electrode forming step. The heat treatment makes it possible to deposit the oxygen precipitates described above, and the oxygen precipitates can act as gettering sinks in the subsequent steps.

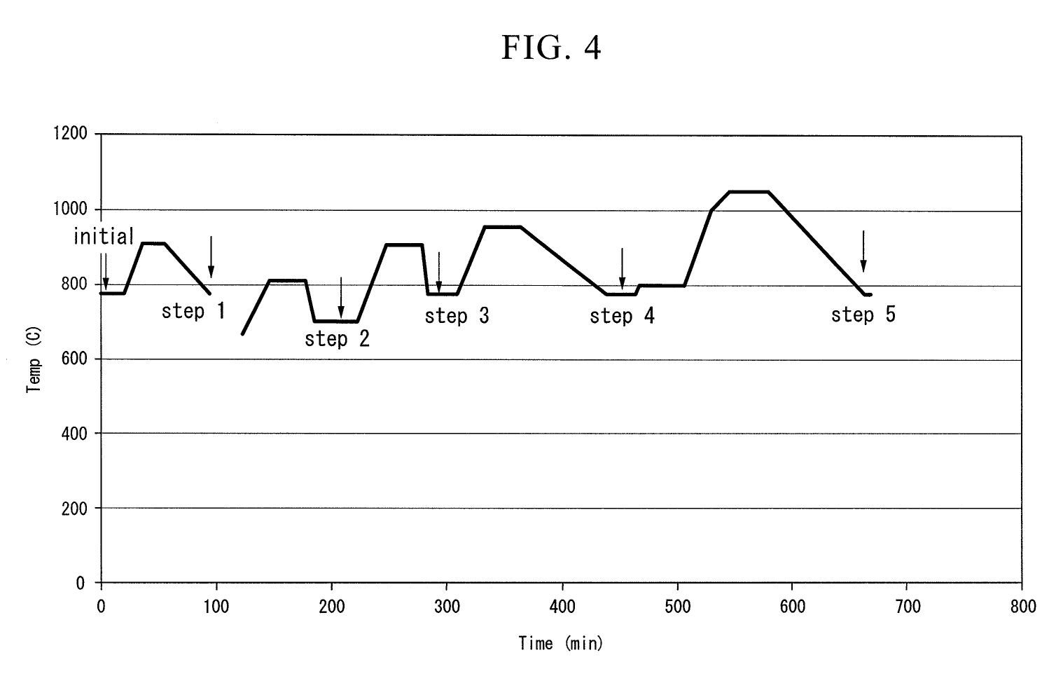

The heat treatment conditions in the device manufacturing process correspond to the conditions shown in FIG. 4.

Specifically, Initial, Step 1, Step 2, Step 3, Step 4, and Step 5 shown in FIG. 4 correspond to the end times of the processes of forming the buried photodiode that is a photoelectric conversion element and manufacturing the transfer transistor by using the silicon substrate W1 having the epitaxial layer formed thereon.

In the heat treatment shown in FIG. 4, the heat treatment of a first process between Initial and Step 1 shown in the figure is performed under conditions in which a rate of temperature increase is 5° C./min, a maintaining time is 30 minutes at a maintaining temperature of 900° C., and a rate of temperature decrease is 3° C./min.

A heat treatment of a second process between Step 1 and Step 2 shown in the figure is performed under conditions in which a rate of temperature increase is 10° C./min, a maintaining time is 100 minutes at a maintaining temperature of 780° C., and a rate of temperature decrease is 10° C./min.

A heat treatment of a third process between Step 2 and Step 3 shown in the figure is performed under conditions in which a rate of temperature increase is 5° C./min, a maintaining time is 30 minutes at a maintaining temperature of 800° C., and a rate of temperature decrease is 5° C./min.

A heat treatment of a fourth process between Step 3 and Step 4 shown in the figure is performed under conditions in which a rate of temperature increase is 5° C./min, a maintaining time is 30 minutes at a maintaining temperature of 1000° C., and a rate of temperature decrease is 2° C./min.

A heat treatment of a fifth process between Step 4 and Step 5 shown in the figure is performed under conditions in which a rate of temperature increase is 10° C./min, a maintaining time is 30 minutes at a maintaining temperature of 1115° C., and a rate of temperature decrease is 3° C./min.

Here, the heat treatment of the first process between Initial and Step 1 shown in the figure is performed by holding the temperature at 900° C. for 30 minutes, and this is different from the condition of the heat treatment step S5 of the present embodiment which is performed at a temperature of 600 to 800° C. for 0.25 to 3 hours. However, in this first process, oxygen precipitates having a minute size distribution are formed at high density due to carbon contained in the carbon compound layer W2. In addition, the condensation of an oxygen precipitate of excessive size is suppressed. Accordingly, in the subsequent second and third processes, the oxygen precipitates acting as the gettering sinks can be properly formed.

In the method for manufacturing a silicon substrate for a solid-state imaging device according to the present embodiment, the heat treatment corresponding to the heat treatment step S5 may be performed separately from the device manufacturing process. In this case, it is preferable that the silicon substrate W0 having the carbon compound layer W2 and the epitaxial layers W3 and W4 formed thereon be subjected to the heat treatment at a temperature of 600 to 800° C. for 0.25 to 3 hours. It is preferable that the heat treatment atmosphere be a mixed gas of oxygen and an inert gas such as argon, nitrogen, or the like. This heat treatment allows the oxygen precipitates that are carbon/oxygen-based complexes to precipitate while the carbon at substitution site acts as an origin of the precipitate in the carbon compound layer W2; thereby, the gettering layer W9 is formed at the position corresponding to the carbon compound layer W2 and the vicinity thereof as shown in FIG. 1(e). As a result, the silicon substrate can exert an IG (gettering) effect.

If the heat treatment for exerting the IG effect is conducted at a temperature lower than the above-mentioned temperature range, regardless of whether the heat treatment is conducted in or before the device manufacturing process, the complexes of carbon and oxygen are formed insufficiently. As a result, sufficient gettering effect cannot be exhibited when metal contamination occurs in the substrate, and therefore, it is not preferable. On the other hand, if the heat treatment is conducted at a temperature higher than the above-mentioned temperature range, an excessively large amount of oxygen precipitates are agglutinated. As a result, the density of the gettering sinks is insufficient, and therefore, it is not preferable.

The manufacturing process of a solid-state imaging device includes a heat treatment step at a temperature of about 600 to 800° C. Accordingly, by using the above-mentioned epitaxial substrate (the silicon substrate W0 which has the epitaxial layers W3 and W4 formed thereon) in the manufacturing process of a solid-state imaging device, it is possible to grow and form the oxygen precipitates naturally by the device manufacturing process. Specifically, while depending on the conditions regarding the heat treatment temperature of the device manufacturing process, the formation of nuclei of complexes of carbon and oxygen is accelerated by the low-temperature heat treatment, and the nuclei are grown by the high-temperature heat treatment to become sinks effective in gettering. In this manner, the formation and growth of the nuclei of oxygen precipitates that are the carbon/oxygen-based complexes are progressed (oxygen precipitates naturally precipitate in the device manufacturing process). As a result, it is possible to form a gettering layer in which the oxygen precipitates having high gettering effect for metal contamination are formed, immediately below the epitaxial layer in the device manufacturing process. Therefore, a proximity gettering can be realized.

As described above, a solid-state imaging device manufactured by using the silicon substrate W1 for a solid-state imaging device of the present embodiment makes it possible to suppress contamination by heavy metal during the manufacturing process and prevent the generation of particles. Accordingly, a high-performance solid-state imaging device having high electrical characteristics can be manufactured at a high yield.

In addition, in the case where a buried photodiode of the solid-state imaging device is formed at a portion corresponding to the second epitaxial layer W4, a gettering layer is situated immediately below the region where the buried photodiode is formed; therefore, the region where the buried photodiode is formed and the gettering layer contact with each other. This can further enhance the gettering efficiency to getter heavy metal.

### Second Embodiment

Hereinafter, a second embodiment of the present invention will be described with reference to the accompanying drawings.

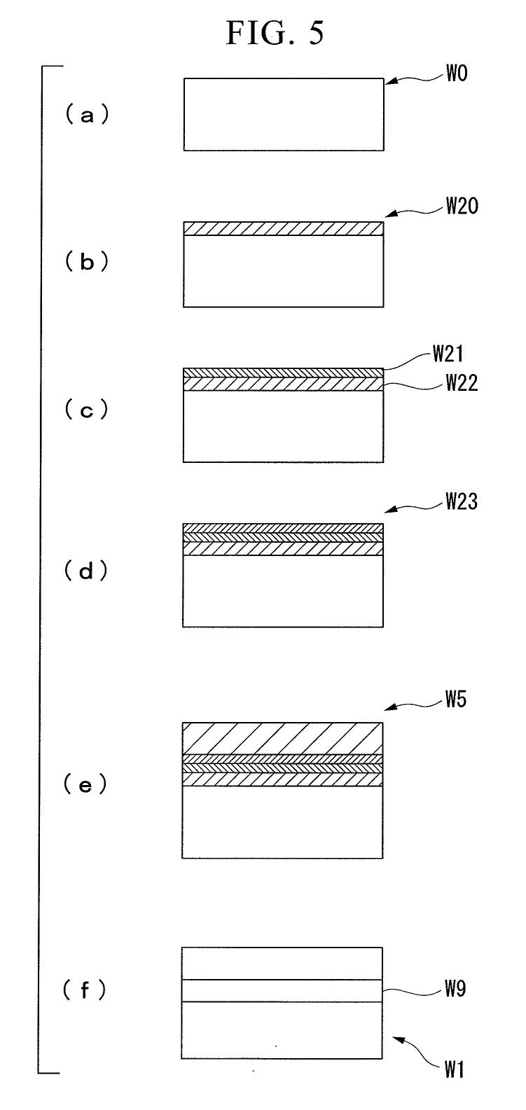

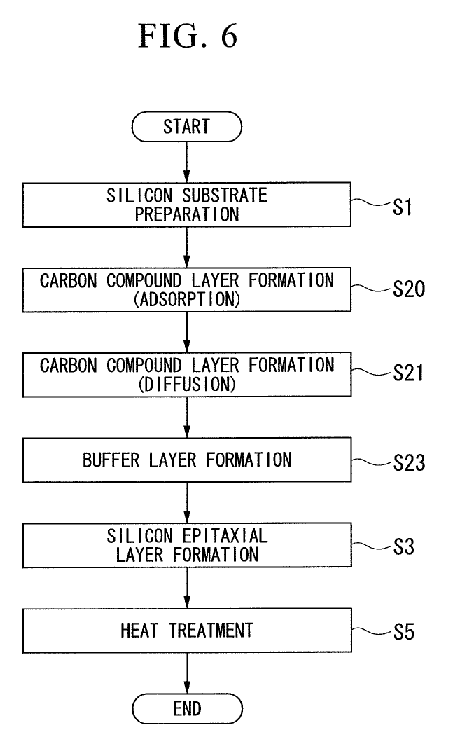

FIG. 5 is a front cross-sectional view showing a method for manufacturing a silicon substrate according to the present embodiment. FIG. 6 is a flowchart showing the manufacturing method according to the present embodiment.

In the present embodiment, components similar to those of the first embodiment described above are denoted by the same reference numerals, and detailed descriptions thereof will be omitted.

The method for manufacturing a silicon substrate for a solid-state imaging device according to the present embodiment includes, as shown in FIG. 6, a silicon substrate preparing step S1, a carbon compound layer forming (adsorption) step S20, a carbon compound layer forming (diffusion) step S21, a buffer layer forming step S23, a silicon epitaxial layer forming step S3, and a heat treatment step S5.

In the silicon substrate preparing step S1, as shown in FIG. 5(a), the silicon substrate W0 is prepared in the same manner. Next, in the carbon compound layer forming (adsorption) step S20 shown in FIG. 6, in order to form a carbon compound layer, while maintaining the substrate temperature at 1000° C. or less, the gas sources of organometallic compounds and oxygen are introduced to the surface of the silicon substrate W0; thereby, as shown in FIG. 5B, carbon compounds W20 are adsorbed onto the surface of the silicon substrate W0.

In this case, as the gas source of organometallic compounds, there is an organic silane gas source such as trimethylsilane or the like, and as the gas source of oxygen, there is a gas source containing oxygen such as O₂, CO₂, or N₂O. With regard to forming conditions such as concentrations, film thicknesses, and the like, the ratio of the introduced gas sources (the gas source of organometallic compounds: the gas source of oxygen) is preferably in a range of 5:1 to 3:1, more preferably, 5:1, 4:1, or 3:1, and most preferably, 5:1. Simultaneously, it is preferable that the temperature conditions or the like be in a range of 600 to 1000° C.

Next, in the carbon compound layer forming (diffusion) step S21 shown in FIG. 6, as shown in FIG. 5(c), a rapid thermal processing is performed in order to diffuse the carbon compounds W20 adsorbed on the surface into the internal of the silicon substrate W0.

During this rapid thermal processing, the process conditions are set such that a carbon compound diffusion layer (carbon compound layer) W22 is formed in the silicon substrate W0, and a carbon-free region W21 is formed above this carbon compound diffusion layer W22 and below the surface of the silicon substrate W0.

Specifically, a rate of temperature increase is preferably in a range of 40 to 60° C./min, more preferably, 40, 50, or 60° C./min, and most preferably 50° C./min. A rate of temperature decrease is preferably in a range of 60 to 85° C./min, more preferably, 60, 75, or 85° C./min, and most preferably 75° C./min. The temperature conditions preferably include a maintaining time of 10 to 300 sec at a temperature of 650 to 750° C., and more preferably, includes a maintaining time of 300 sec at a temperature of 750° C.

It is preferable that the thicknesses of the carbon compound diffusion layer W22 and the carbon-free region W21 be in a range of 10 to 100 nm.

In addition, in order to maintain the integrity of the carbon compound diffusion layer (carbon compound layer) W22, the silicon substrate W0 is maintained at a low temperature of 1000° C. or less.

Next, in the buffer layer forming step S23 shown in FIG. 6, as shown in FIG. 5(d), a buffer layer (a single-crystal silicon epitaxial film) W23 is formed above the carbon compound diffusion layer W22 formed by the rapid thermal processing (immediately above the carbon-free region W21). Specifically, while setting a growth temperature to be 1000° C. or less, a silicon single crystal is epitaxially grown by using disilane or monosilane to form the buffer layer W23. This buffer layer W23 makes it possible to suppress the diffusion of impurities from the carbon compound diffusion layer (carbon compound layer).

It is preferable that the thickness of the buffer layer W23 be in a range of 2 to 10 μm.

Next, in the silicon epitaxial layer forming step S3 shown in FIG. 6, as shown in FIG. 5(e), an epitaxial layer W5 is formed immediately above the surface of the buffer layer W23.

Next, in the heat treatment step S5 shown in FIG. 6, by performing a heat treatment in the device manufacturing process of a solid-state imaging device, a gettering layer W9 is formed as shown in FIG. 5F which acts as a gettering sink in the manufacturing process of a solid-state imaging device. This gettering layer W9 is formed at the positions corresponding to the carbon compound diffusion layer W22 and the carbon-free region W21.

Since the carbon compound diffusion layer W22 is a carbon-rich layer, the formation of carbon/oxygen-based complexes is accelerated by a low-temperature heat treatment at a temperature of 600 to 800° C.; thereby, oxygen precipitation can be facilitated.

The manufacturing process of a solid-state imaging device includes a heat treatment step at a temperature of about 600 to 800° C. Accordingly, by using the above-mentioned epitaxial substrate (the silicon substrate W0 which has the epitaxial layer W5 formed thereon) in the manufacturing process of a solid-state imaging device, it is possible to grow and form the oxygen precipitates naturally by the device manufacturing process. Specifically, while depending on the conditions regarding the heat treatment temperature of the device manufacturing process, the formation of nuclei of complexes of carbon and oxygen is accelerated by the low-temperature heat treatment, and the nuclei are grown by the high-temperature heat treatment to become sinks effective in gettering. In this manner, the formation and growth of the nuclei of oxygen precipitates that are the carbon/oxygen-based complexes are progressed (oxygen precipitates naturally precipitate in the device manufacturing process). As a result, it is possible to form a gettering layer in which the oxygen precipitates having high gettering effect for metal contamination are formed, below the epitaxial layer W5 in the device manufacturing process. Therefore, a proximity gettering can be realized.

As described above, a solid-state imaging device manufactured by using the silicon substrate W1 for a solid-state imaging device of the present embodiment makes it possible to suppress contamination by heavy metal during the manufacturing process and prevent the generation of particles. Accordingly, a high-performance solid-state imaging device having high electrical characteristics can be manufactured at a high yield.

In addition, in the present invention, it is preferable that a single-crystal silicon substrate doped with boron at a concentration of 1.0×10¹⁵ to 1.0×10¹⁹ atoms/cm³ be used as the silicon substrate W0. In this case, the oxygen precipitates are more likely to be agglutinated by the heat treatment, as compared to the cases of using silicon substrates doped with other dopants. Therefore, it is possible to manufacture a silicon substrate W1 for a solid-state imaging device capable of attaining higher gettering efficiency to getter heavy metal. In the case in which a single-crystal silicon substrate doped with boron is used, it is preferable that the oxygen concentration of the single-crystal silicon substrate be in a range of 14×10¹⁷ to 18×10¹⁷ atoms/cm³, and at this high oxygen concentration, the growth of precipitate nuclei of the oxygen precipitates can be accelerated. Accordingly, agglutination of the oxygen precipitates during the heat treatment which is caused by boron significantly occurs, and it is possible to manufacture a silicon substrate for a solid-state imaging device capable of attaining higher gettering efficiency to getter heavy metal.

While preferred embodiments of the invention have been described and illustrated above, it should be understood that these are exemplary of the invention and are not to be considered as limiting. Additions, omissions, substitutions, and other modifications can be made without departing from the spirit or scope of the present invention. Accordingly, the invention is not to be considered as being limited by the foregoing description, and is only limited by the scope of the appended claims.

What is claimed is:

1. A method for manufacturing a silicon substrate for a solid-state imaging device, the method comprising:
a carbon compound layer forming step of forming a carbon compound layer on the surface of a silicon substrate;
an epitaxial step of forming a silicon epitaxial layer on the carbon compound layer; and
a heat treatment step of subjecting the silicon substrate having the epitaxial layer formed thereon to a heat treatment at a temperature of 600 and 800° C. for 0.25 to 3 hours so as to form gettering sinks that are complexes of carbon and oxygen below the epitaxial layer.

2. The method for manufacturing a silicon substrate for a solid-state imaging device according to claim 1,
wherein in the carbon compound layer forming step, the carbon compound layer is formed to have a growth thickness of 0.1 to 1.0 μm.

3. The method for manufacturing a silicon substrate for a solid-state imaging device according to claim 1,
wherein in the carbon compound layer forming step, the carbon compound layer is formed which has a carbon concentration of 1×10¹⁶ to 1×10²⁰ atoms/cm³, and an oxygen concentration of 1.0×10¹⁸ to 1.0×10¹⁹ atoms/cm³.

4. The method for manufacturing a silicon substrate for a solid-state imaging device according to claim 1,
wherein in the carbon compound layer forming step, the carbon compound layer is formed by using an organometallic compound gas and a gas containing oxygen as gas sources.

5. The method for manufacturing a silicon substrate for a solid-state imaging device according to claim 1,
wherein the epitaxial step comprises: forming a first silicon epitaxial layer on the carbon compound layer; lowering the ambient temperature to 1000° C. or less after forming the first silicon epitaxial layer; and forming a second silicon epitaxial layer on the first silicon epitaxial layer.

6. The method for manufacturing a silicon substrate for a solid-state imaging device according to claim 1,
wherein in the carbon compound layer forming step, carbon compounds are adsorbed onto the surface of the silicon substrate using an organometallic compound gas and a gas containing oxygen as gas sources, and then the silicon substrate is subjected to a rapid thermal processing so as to diffuse the carbon compounds into the silicon substrate, thereby, the carbon compound layer is formed.

7. The method for manufacturing a silicon substrate for a solid-state imaging device according to claim 6,
wherein the method further comprises forming a buffer layer directly on the carbon compound layer.

8. The method for manufacturing a silicon substrate for a solid-state imaging device according to claim 1,
wherein the method further comprises forming an oxide film on the epitaxial layer.

9. The method for manufacturing a silicon substrate for a solid-state imaging device according to claim 1,
wherein a single crystal silicon substrate doped with boron at a concentration of 1×10¹⁵ to 1×10¹⁹ atom/cm³ is used as the silicon substrate.

10. A silicon substrate for a solid-state imaging device, which is manufactured by the method according to claim 1 and comprises:
an epitaxial layer positioned on the surface of a silicon substrate; and
a gettering layer which is positioned below the epitaxial layer and includes BMDs having a size of 10 to 100 nm at a concentration of 1.0×10⁶ to 1.0×10⁹ atoms/cm³.
